(19) United States
(12) Patent Application Publication
(10) Pub. No.: US 2026/0309171 A1
(43) Pub. Date: Oct. 8, 2026

(54) TANK ASSEMBLY

(71) Applicant: AMTROL LICENSING INC., WEST WARWICK, RI (US)

(72) Inventors: JUSTIN MANCOVSKY, PROVIDENCE, RI (US); MICHAEL COGLIATI, COVENTRY, RI (US)

(21) Appl. No.: 19/172,725

(22) Filed: Apr. 8, 2025

(51) Int. Cl. F15D 1/00; B65D 88/54; H05K 7/20

(52) U.S. Cl. CPC F15D 1/0005; B65D 88/54; H05K 7/20272; H05K 7/20772

(57) ABSTRACT

Provided is a tank including a tank having an inlet for receiving fluid and an outlet for delivering fluid, the tank assembly defining a cavity for storing fluid, and a flow assembly disposed in the cavity, the flow assembly including a flow modifier for directing fluid from the inlet to the outlet while slowing a flow rate of the fluid.

### TECHNICAL FIELD

In general, the present application relates to a tank assembly, and in particular, to a tank assembly for providing liquid cooling.

### BACKGROUND OF THE INVENTION

Liquid cooling systems may be utilized in data centers to conduct heat away from processors and chipsets. Liquid cooling systems may include direct-to-chip liquid cooling and immersive liquid cooling, for example. Such systems may be considered, amongst others, as “mission critical” systems that operate around the clock with minimal to zero downtime.

### SUMMARY OF THE INVENTION

In accordance with an embodiment of the present application, a tank assembly is provided that includes a tank having an inlet for receiving fluid and an outlet for delivering fluid, the tank assembly defining a cavity for storing fluid, and a flow assembly disposed in the cavity, the flow assembly including a flow modifier for directing fluid from the inlet to the outlet while slowing a flow rate of the fluid.

In accordance with another embodiment of the present application, a tank assembly is provided that includes a tank having an inlet for receiving fluid and an outlet for delivering fluid, the tank assembly defining a cavity for storing fluid, an inlet tube coupled to the tank at the inlet, an outlet tube coupled to the tank at the outlet below the inlet, and a flow assembly disposed in the cavity, the flow assembly including a flow modifier for directing fluid from the inlet to the outlet while slowing a flow rate of the fluid and a central tube coupled to the flow modifier.

In accordance with still another embodiment of the present application, a tank assembly is provided that includes a tank having an inlet for receiving fluid and an outlet for delivering fluid, the tank assembly defining a cavity for storing fluid, an inlet tube coupled to the tank at the inlet, an outlet tube coupled to the tank at the outlet below the inlet, the inlet tube and outlet tube being on opposite sides of the tank and extending in opposite directions from one another perpendicular to a central axis of the tank, and a flow assembly disposed in the cavity, the flow assembly including a flow modifier for directing fluid from the inlet to the outlet while slowing a flow rate of the fluid and a central tube coupled to the flow modifier, wherein the flow modifier has a helical pattern for directing flow from a top of the tank to a bottom of the tank, or wherein the flow modifier includes a plurality of plates spaced from one another along a length of the tank and one or more dividers between each pair of adjacent plates, and wherein each plate includes a plate opening for fluid to flow downward through the tank.

These and other objects of this invention will be evident when viewed in light of the drawings, detailed description and appended claims.

### BRIEF DESCRIPTION OF THE DRAWINGS

The application may take physical form in certain parts and arrangements of parts, a preferred embodiment of which will be described in detail in the specification and illustrated in the accompanying drawings which form a part hereof, and wherein:

FIG. 1 is a perspective view of an exemplary tank assembly.

FIG. 2 is a cross-sectional view of the tank assembly taken along line 2-2 in FIG. 1.

FIG. 3 is another cross-sectional view of the tank assembly taken along line 3-3 in FIG. 1.

FIG. 4 is another cross-sectional view of the tank assembly taken along line 4-4 in FIG. 1.

FIG. 5 is a perspective view of the tank assembly where the domes and shell of the tank are shown being transparent.

FIG. 6 is a perspective view of another exemplary tank assembly.

FIG. 7 is a cross-sectional view of the tank assembly taken along line 7-7 in FIG. 6.

FIG. 8 is another cross-sectional view of the tank assembly taken along line 8-8 in FIG. 6.

FIG. 9 is another cross-sectional view of the tank assembly taken along line 9-9 in FIG. 6.

FIG. 10 is a perspective view of the tank assembly where the domes and shell of the tank are shown being transparent.

FIG. 11 is a cross-sectional view of still another exemplary tank assembly.

FIG. 12 is a perspective view of a further exemplary tank assembly where the domes and shell of the tank are shown being transparent.

FIG. 13 is a perspective view of still another exemplary tank assembly where the tank is shown as being transparent.

FIG. 14 is a perspective view of a flow modifier.

FIG. 15 is a perspective view of another flow modifier.

### DETAILED DESCRIPTION OF THE INVENTION

Embodiments of the application relate to methods and systems for a tank assembly that includes a tank having an inlet for receiving fluid and an outlet for delivering fluid, the tank assembly defining a cavity for storing fluid, and a flow assembly disposed in the cavity, the flow assembly including a flow modifier for directing fluid from the inlet to the outlet while slowing a flow rate of the fluid. The systems and methods described herein can provide liquid cooling solutions, for example in data centers. Chipsets in a column may be submersed in fluid and connected to a cooling system to remove heat from the chipset. Cooled fluid from the cooling system may be provided to the tank of the present application where the flow rate of the fluid is slowed and the cooled fluid may be stored as a reserve. In certain circumstances, heated fluid may be directed into the tank, and the configuration of the tank allows the fluid to be routed horizontally and then directed in a helical pattern to slow the flow rate while increasing the distance the fluid travels and extending the time that cooled fluid may be provided to the system.

With reference to the drawings, like reference numerals designate identical or corresponding parts throughout the several views. However, the inclusion of like elements in different views does not mean a given embodiment necessarily includes such elements or that all embodiments of the invention include such elements. The examples and figures are illustrative only and not meant to limit the invention, which is measured by the scope and spirit of the claims.

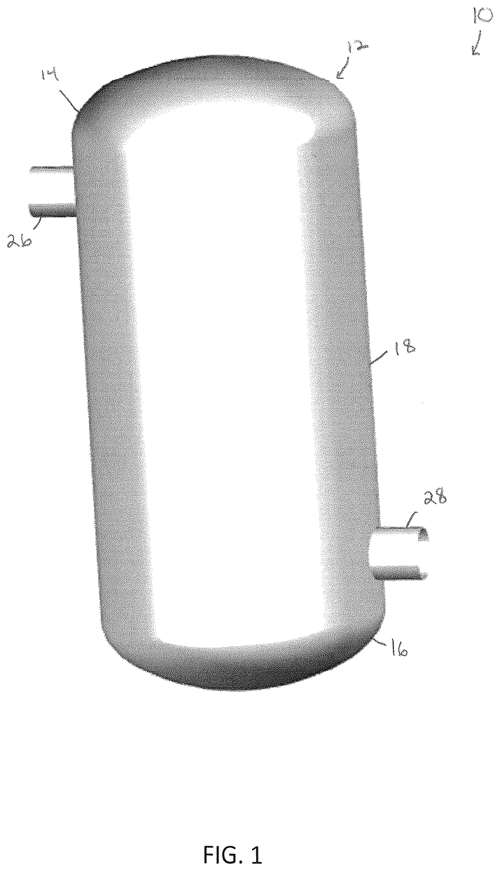

Turning initially to FIG. 1, an exemplary tank assembly is illustrated generally at reference numeral 10. The tank assembly 10 may be a pressure vessel made of a suitable material, such as metal, composite material, etc. for use in a data center or other mission critical system. The tank assembly 10 includes a tank 12 formed by an upper dome 14, a lower dome 16, and a shell 18 having a first end connected to the upper dome 14 and a second end connected to the lower dome 16. The upper dome 14, the lower dome 16, and the shell 18 form a cavity 20 for receiving/holding a fluid, such as water. It will be appreciated, however, that the tank 12 may include any suitable number pieces coupled in a suitable manner.

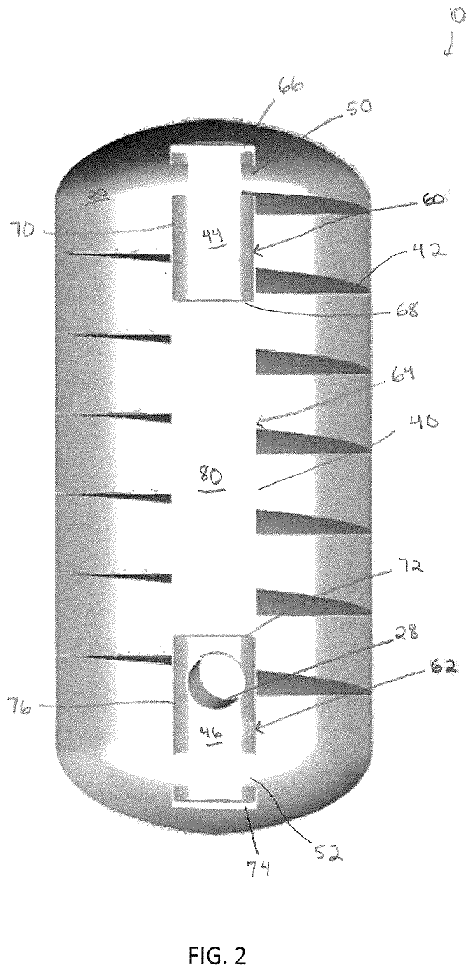

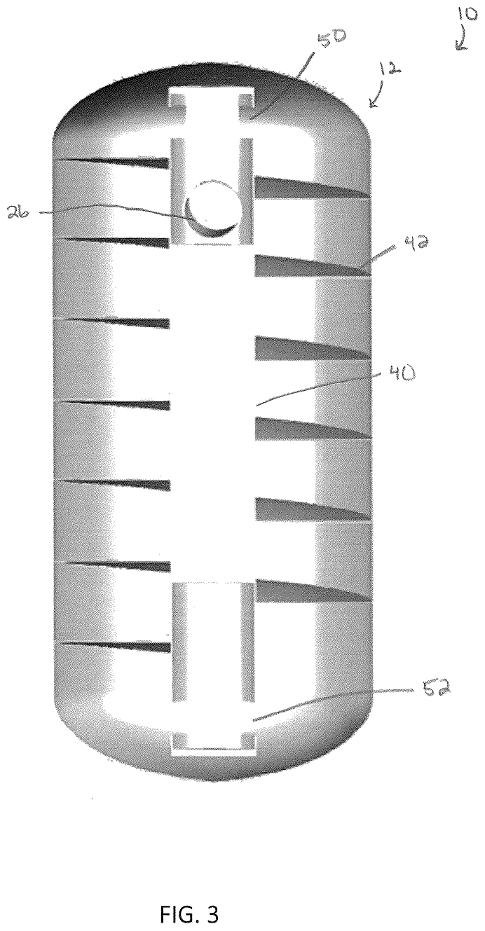

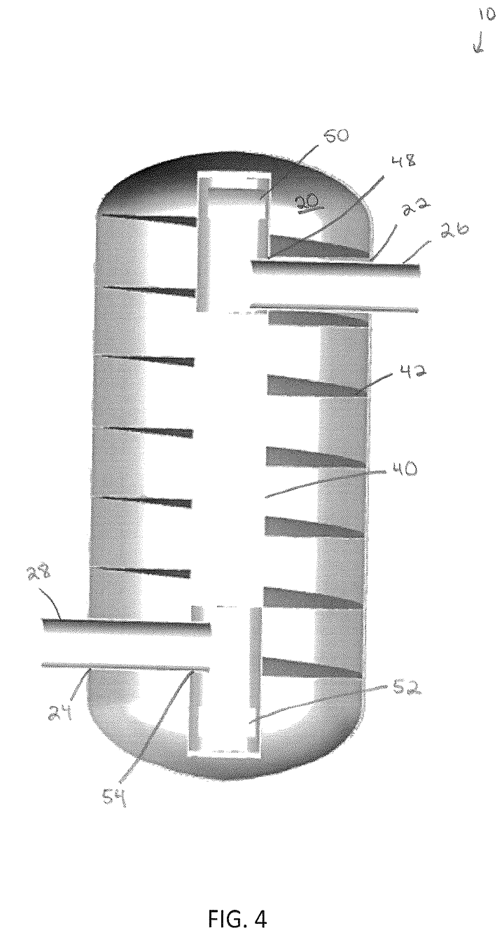

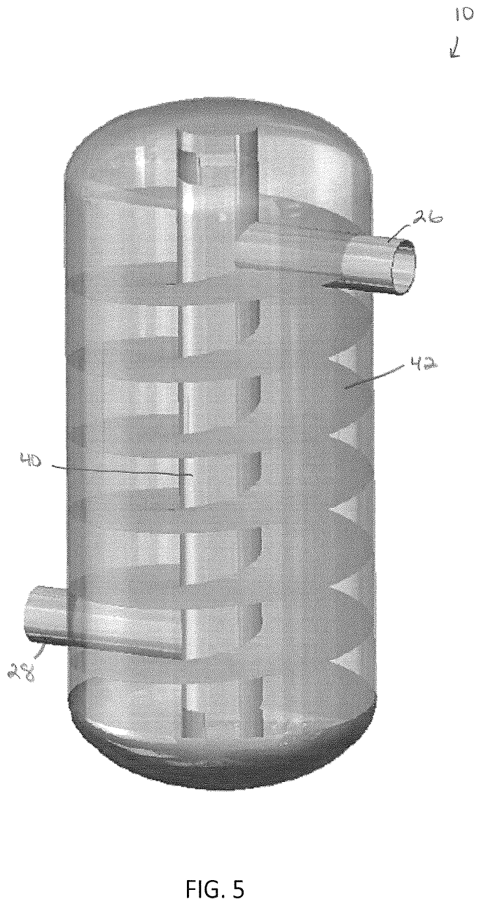

Turning additionally to FIGS. 2-5, the shell 18 includes a first opening 22 near the first end and a second opening 24 near the second end though which respective first and second tubes 26 and 28 extend. The first and second openings 22 and 24 may be formed on opposite sides of the tank 12 such that the first and second tubes 26 and 28 extend perpendicular to a central axis of the tank 12 in opposite direction from one another. It will be appreciated, however, that the inlet and outlet may be on the same side as one another, and/or angled relative to one another, and/or on the top or bottom of the tank. The first tube 26 serves as an inlet for receiving fluid, such as heated fluid, and the second tube 28 serves as an outlet for delivering fluid, such as cooled fluid, to a component stack in a data center. Flow rates in these systems are high, for example three hundred gallons per minute or more, and turbulent flow is directed into the tank. The first and second tubes 26 and 28 promote laminar flow of fluid. The first and second tubes 26 and 28 may be coupled to the shell 18 in a suitable manner, such as welding, or may be integrally formed with the shell 18. It will also be appreciated that the first and second openings 22 and 24 may be formed in the upper and lower domes 14 and 16 respectively, or formed in one of the domes 14 or 16 and the shell 18.

Disposed in the cavity 20 of the tank 12 is a flow assembly including a central tube 40 coupled to the first and second tubes 26 and 28 and a flow modifier 42 coupled to the central tube 40 and/or an inner surface of the tank 12. The central tube 40 extends along a length of the tank 12 and includes a first cavity 44, a second cavity 46, a first inlet opening 48 through which the first tube 26 extends into the first cavity 44, one or more first outlet openings 50 through which fluid exits the first cavity 44 of the central tube 40, one or more second inlet openings 52 through which fluid enters the second cavity 46 of the central tube 40, and a second outlet opening 54 through which the second tube 28 extends into the second cavity 46. The first and second tubes 26 and 28 may be coupled to the central tube 40 in a suitable manner, such as welding, or may be integrally formed with the central tube 40, and the flow modifier 42 may be coupled to the central tube 40 and/or tank 12 in a suitable manner, such as by welding, or may be integrally formed therewith.

The central tube 40 may include at least three portions, a first portion 60 defining the first cavity 44, a second portion 62 defining the second cavity 46, and a third portion 64 between the first and second portions 60 and 62. The third portion 64 may be solid or hollow and the heights of the first portion 60, the second portion 62, and the third portion 64 may be adjusted based on desired flow characteristics of the tank assembly 10. The first portion 60 has a top and bottom 66 and 68 that define with a sidewall 70 the first cavity 44, and the second portion 62 has a top and bottom 72 and 74 that define with a sidewall 76 the second cavity 46. In an implementation, the bottom 68 of the first portion 60 and the top 72 of the second portion 62 define with a sidewall 78 a third cavity 80 in the third portion 64. It will be appreciated that the portions may be integrally formed or separate components.

Turning now to the flow modifier 42, the flow modifier 42 is provided in the cavity 20 of the tank 12 to slow down fluid flow, optimize heat transfer, minimize mixing of thermal layers, and mitigate effects of non-isothermal flow. The flow modifier 42 may extend along a length of the tank 12, from a position below the first outlet opening 50 to receive fluid from the inlet to a position above the second inlet opening 52 to deliver fluid to the outlet allowing for the controlled flow of fluid along the length of the tank 12. The flow modifier 42 may be formed by a plurality of curved surfaces with variable pitch along the length of the flow modifier 42 defining a curved path to induce stratification of fluid to maintain temperature gradients. For example, the flow modifier 42 may have a helical pattern designed to direct flow from the top of the tank 12 to the bottom of the tank 12. The flow modifier 42 may be made of a suitable material, such as a metal, a polymer, a composite, etc. The flow modifier 42 may be thermally conductive to facilitate heat exchange between fluid zones.

The first tube 26 may extend through the tank 12 and central tube 40 between first and second coils of the flow modifier 42. Similarly, the second tube 28 may extend through the tank 12 and central tube 40 between sixth and seventh coils of the flow modifier 42, which as illustrated are the bottom two coils. It will be appreciated however, that the first and second tubes 26 and 28 may enter the tank 12 at positions above or below as shown in FIG. 1 depending on desired flow characteristics.

During operation, fluid enters the tank assembly 12 via the first tube 26. The fluid flow through the first tube 26 into the first cavity 44 of the central tube 40, where the fluid exits the central tube 40 via the first outlet opening 50. The fluid flows along the flow modifier from a top of the tank to a bottom of the tank along the curved path, where the fluid enters the second cavity 46 of the central tube 40 via the second inlet opening 52. The fluid then flows from the second cavity 46 to the second tube 28 where the fluid exits the tank assembly 10. In an implementation, the tank 12 may include one or more ports for receiving a sensor for monitoring temperature, pressure, and fluid conditions within the cavity 20 as the fluid flows therethrough.

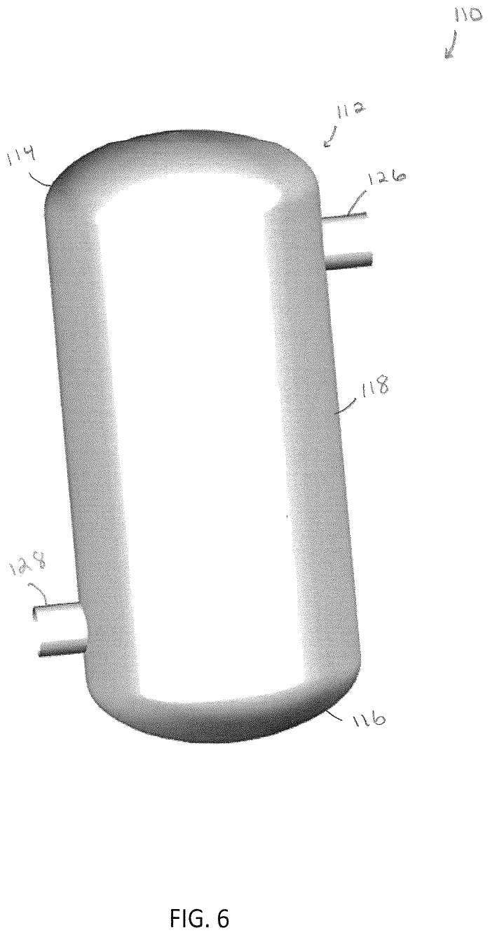

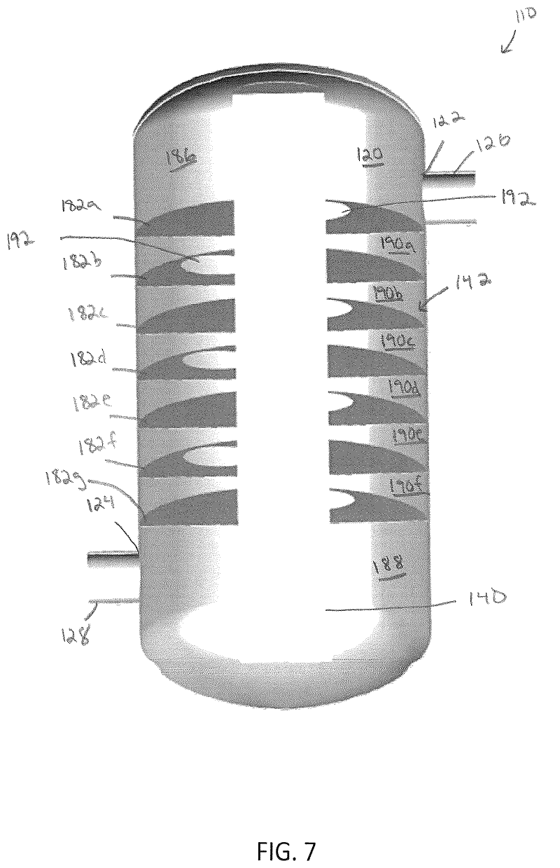

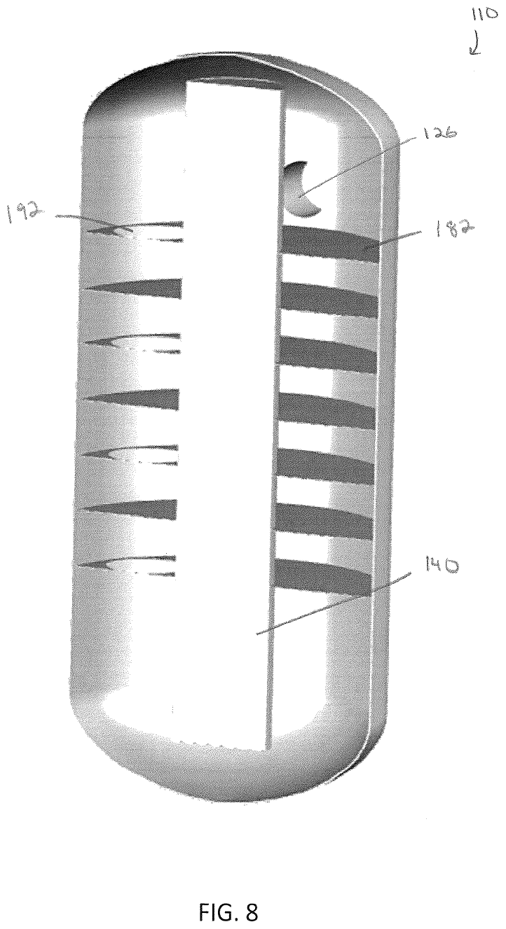

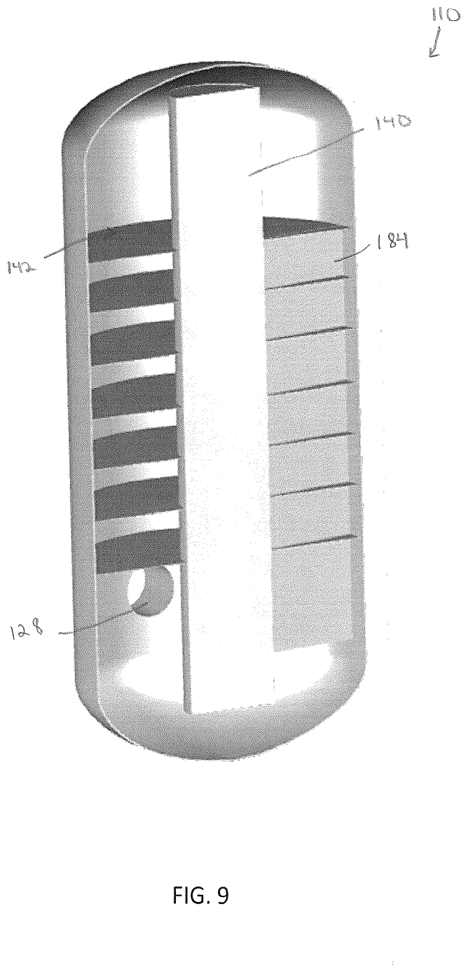

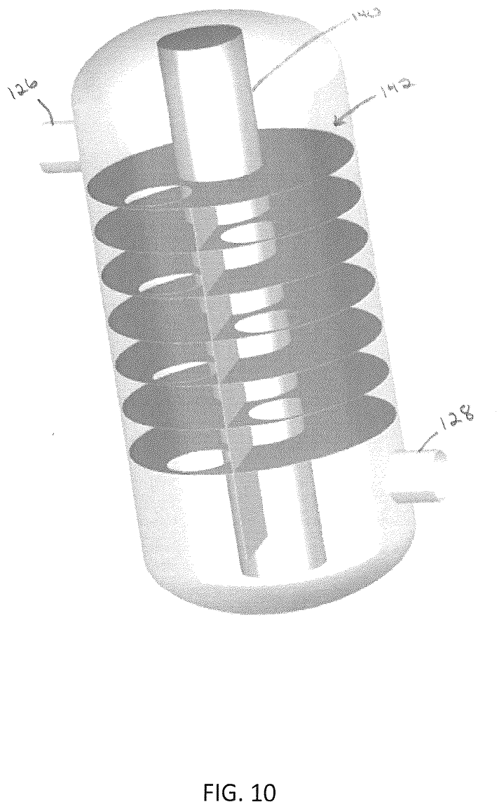

Turning now to FIGS. 6-10, an exemplary embodiment of the tank assembly is shown at 110. The tank assembly 110 is substantially the same as the above-referenced tank assembly 10, and consequently the same reference numerals but indexed by 100 are used to denote structures corresponding to similar structures in the tank assemblies. In addition, the foregoing description of the tank assembly 10 is equally applicable to the tank assembly 110 except as noted below.

The tank assembly 110 includes a tank 112 formed by an upper dome 114, a lower dome 116, and a shell 118 having a first end connected to the upper dome 114 and a second end connected to the lower dome 116. The upper dome 114, lower dome 116, and shell 118 form a cavity 120 for receiving/holding a fluid, such as water. It will be appreciated, however, that the tank may include any suitable number pieces coupled in a suitable manner.

The shell 118 includes a first opening 122 near the first end and a second opening 124 near the second end though which respective first and second tubes 126 and 128 extend. The first and second openings 122 and 124 are formed on opposite sides of the tank 12 such that the first and second tubes 126 and 128 extend perpendicular to a central axis of the tank 112. The first tube 126 serves as an inlet for receiving fluid, such as heated fluid, and the second tube 128 serves as an outlet for delivering fluid, such as cooled fluid, to a component stack in a data center. The first and second tubes 126 and 128 may be coupled to the shell 118 in a suitable manner, such as welding, or may be integrally formed with the shell 118. It will also be appreciated that the first and second openings 122 and 124 may be formed in the upper and lower domes 114 and 116 respectively, or formed in one of the domes 114 or 116 and the shell 118.

Disposed in the cavity 120 of the tank 112 is a central tube 140 and a flow modifier 142 coupled to the central tube 140 and an inner surface of the tank 112. The flow modifier 142 may be coupled to the central tube 140 and/or tank 112 in a suitable manner, such as by welding, or may be integrally formed therewith. The central tube 140 extends along a length of the tank 112 and may be hollow or solid.

The flow modifier 142 is provided in the cavity 120 of the tank 112 to optimize heat transfer, minimize mixing of thermal layers, and mitigate effects of non-isothermal flow. The flow modifier 142 may extend along a length of the tank 112, from a position below the first tube 126 to receive fluid from the inlet to a position above the second tube 128 to deliver fluid to the outlet allowing for the controlled flow of fluid along the length of the tank 112. The flow modifier 142 may be formed by a plurality of plates 182a-182g spaced from one another along a length of the tank 112 and one or more dividers 184, and as shown a divider 184 between each pair of adjacent plates 182 to direct flow around the plates 182 to increase the flow path of the fluid. The dividers 184 may be coupled to the plates 182 in a suitable manner, such as welding, or may be integrally formed therewith. It will also be appreciated that the divider may be formed in one or more pieces that extend along the length of the tank 12 such that ends of the plates 182 are coupled to sides of the dividers 184.

Each plate 182 extends to the inner surface of the tank 112 and is coupled to the inner surface to prevent flow between the tank 112 and the plates 182. The topmost plate 182a defines with the dome 114 an inlet chamber 186, the bottommost plate 182g defines with the dome 116 an outlet chamber 188, and each pair of adjacent plates 182b-182f define therebetween a chamber 190a-190f for receiving fluid. As shown, the plates 182 are substantially parallel to one another and perpendicular to the central tube 140, although it will be appreciated that the plates could be configured with curves surfaces having variable pitch. It will also be appreciated that any suitable numbers of plates 182 may be utilized.

Each plate 182 includes an opening 192 allowing fluid to flow through the plate 182 to the chamber 190 or 188 below it. As shown, the openings 192 are staggered on opposite sides of the dividers 184 from adjacent plates 182 to increase a travel distance of the fluid flowing through the tank 112. For example, fluid enters the tank 112 via the first tube 126 and is directed to the inlet chamber 186 where the fluid flows through the opening 192 in the topmost plate 182a to the chamber 190a between the plates 182a and 182b. The opening 192 in the plate 182b is positioned on an opposite side of the plate 184 from where the fluid enters the chamber 190a, and thus the fluid flows approximate three hundred sixty degrees around the plate 182b to exit the opening 192 to the chamber 190b between the plates 182b and 182c. Similarly, the opening 192 in the plate 182c is positioned on an opposite side of the plate 184 from where the fluid enters the chamber 190b, and thus the fluid flows approximate three hundred sixty degrees around the plate 182c to exit the opening 192 to the chamber 190c. As shown, the openings 192 are vertically aligned with each other in every other plate 182. That is, the openings 192 in plates 182a, 182c, 182e, and 182g are aligned, and the openings 192 in plates 182b, 182d, and 182f are aligned.

During operation, fluid enters the tank assembly 112 via the first tube 126. The fluid flow through the first tube 126 into the inlet chamber 186, where the fluid exits the inlet chamber 186 via the opening 192 in the plate 182a. The fluid flows along the flow modifier 142 through successive chamber 190a-f and corresponding openings 192 to the outlet chamber 188. The fluid then flows from the outlet chamber 188 to the second tube 128 where the fluid exits the tank assembly 110.

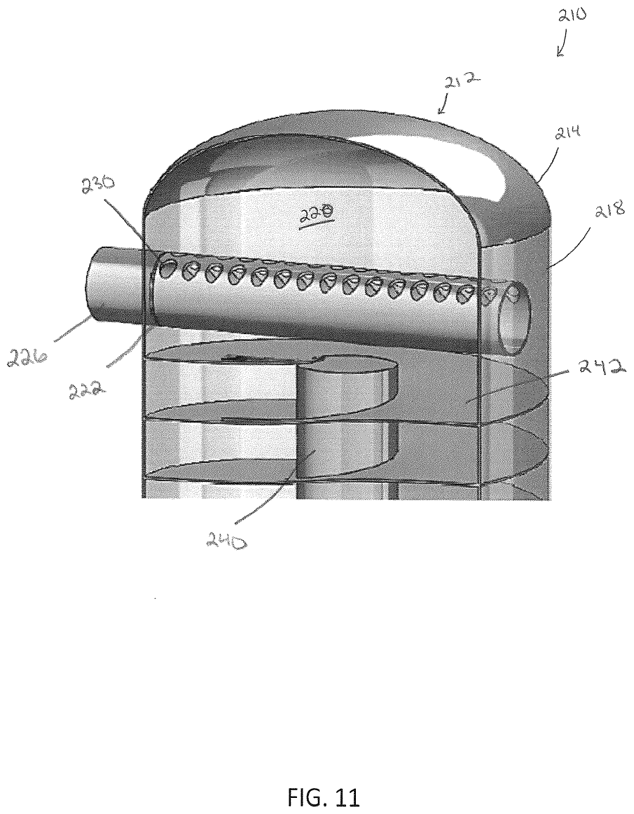

Turning now to FIG. 11, an exemplary embodiment of the tank assembly is shown at 210. The tank assembly 210 is substantially the same as the above-referenced tank assembly 10, and consequently the same reference numerals but indexed by 200 are used to denote structures corresponding to similar structures in the tank assemblies. In addition, the foregoing description of the tank assembly 10 is equally applicable to the tank assembly 210 except as noted below.

The tank assembly 210 includes a tank 212 formed by an upper dome 214, a lower dome, and a shell 218 having a first end connected to the upper dome 214 and a second end connected to the lower dome. The upper dome 214, lower dome, and shell 218 form a cavity 220 for receiving/holding a fluid, such as water. It will be appreciated, however, that the tank may include any suitable number pieces coupled in a suitable manner.

The shell 218 includes a first opening 222 near the first end through which a first tube 226 extends and a second opening near the second end though which a second tube extends. The first opening 222 and the second opening are formed on opposite sides of the tank 212 such that the first tube 226 and the second tube extend perpendicular to a central axis of the tank 212. The first tube 226 serves as an inlet for receiving fluid, such as heated fluid, and the second tube serves as an outlet for delivering fluid, such as cooled fluid, to a component stack in a data center. The first tube 226 and the second tube may be coupled to the shell 218 in a suitable manner, such as welding, or may be integrally formed with the shell 218. It will also be appreciated that the first opening 222 and the second opening may be formed in the upper dome 214 and lower dome respectively, or formed in one of the domes and the shell 228.

The first tube 226 may extend from outside the tank 212 along a width of the tank 212 such that a first end of the first tube 226 extends outside of the tank 212 and a second end of the first tube 226 is coupled to an inner surface of the tank 212 on an opposite side of the opening 222. The first tube 226 includes a plurality of openings 230 extending along its length within the cavity 220, and as shown a plurality of rows of openings 230. The rows of openings 230 are circumferentially spaced from one another and are provided on an upper half of the first tube 226 such that fluid flowing through the first tube 226 may enter the cavity 220 in an upward direction via the plurality of openings 230.

Disposed in the cavity 220 of the tank 212 is a central tube 240 and a flow modifier 242 coupled to the central tube 240 and/or an inner surface of the tank 212. The flow modifier 242 may be coupled to the central tube 240 and/or tank 212 in a suitable manner, such as by welding, or may be integrally formed therewith. The central tube 240 extends along a length of the tank 212 and may be hollow or solid.

The flow modifier 242 may extend along a length of the tank 212, from a position below the inlet tube 226 to receive fluid from the plurality of openings 230 in the inlet tube 226 to a position above the outlet tube to deliver fluid to the outlet allowing for the controlled flow of fluid along the length of the tank 212. The flow modifier 242 may be formed by a plurality of curved surfaces with variable pitch along the length of the flow modifier 242 defining a curved path to induce stratification of fluid to maintain temperature gradients. For example, the flow modifier 242 may have a helical pattern designed to direct flow from the top of the tank 212 to the bottom of the tank 212. Alternatively, it will be appreciated that the flow modifier 242 may be configured similar to the flow modifier 142 in FIGS. 6-10.

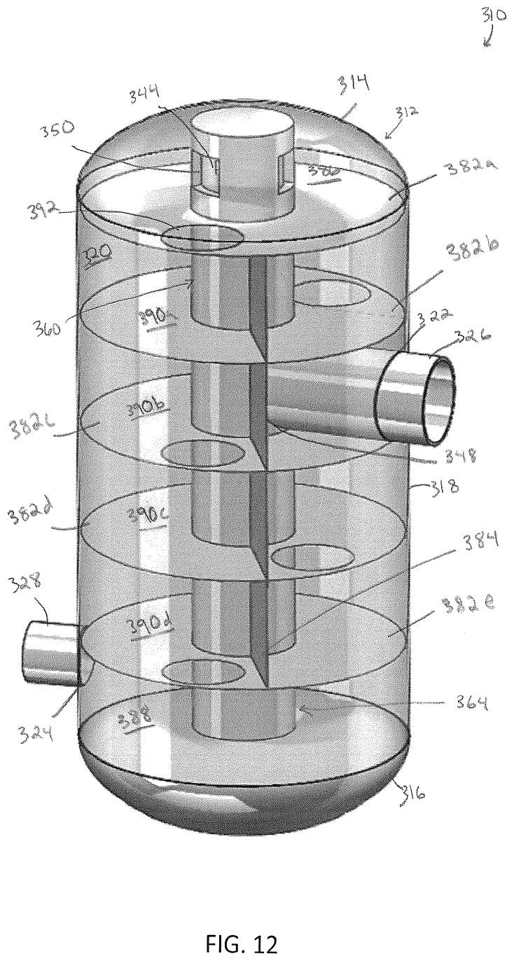

Turning now to FIG. 12, an exemplary embodiment of the tank assembly is shown at 310. The tank assembly 310 is substantially the same as the above-referenced tank assembly 10, and consequently the same reference numerals but indexed by 300 are used to denote structures corresponding to similar structures in the tank assemblies. In addition, the foregoing description of the tank assembly 10 is equally applicable to the tank assembly 310 except as noted below.

The tank assembly 310 includes a tank 312 formed by an upper dome 314, a lower dome 316, and a shell 318 having a first end connected to the upper dome 314 and a second end connected to the lower dome 316. The upper dome 314, lower dome 316, and shell 318 form a cavity 320 for receiving/holding a fluid, such as water. It will be appreciated, however, that the tank may include any suitable number pieces coupled in a suitable manner.

The shell 318 includes a first opening 322 and a second opening 324 though which respective first and second tubes 326 and 328 extend, where the first opening is closer to a middle of the shell 318 than a first end of the tank 312 and the second opening 324 is near the second end of the tank 312. The first and second openings 322 and 324 may be formed on opposite sides of the tank 12 such that the first and second tubes 326 and 328 extend perpendicular to a central axis of the tank 312. The first tube 326 serves as an inlet for receiving fluid, such as heated fluid, and the second tube 328 serves as an outlet for delivering fluid, such as cooled fluid, to a component stack in a data center. The first and second tubes 326 and 328 may be coupled to the shell 318 in a suitable manner, such as welding, or may be integrally formed with the shell 318.

Disposed in the cavity 320 of the tank 312 is a central tube 340 and a flow modifier 342 coupled to the central tube 340 and an inner surface of the tank 312. The central tube 340 extends along a length of the tank 312 and includes a cavity 344, an inlet opening 348 through which the first tube 326 extends into the cavity 344, and one or more outlet openings 350 through which fluid exits the cavity 344 of the central tube 40. The first tube 326 may be coupled to the central tube 340 in a suitable manner, such as welding, or may be integrally formed with the central tube 340, and the flow modifier 342 may be coupled to the central tube 340 and/or tank 312 in a suitable manner, such as by welding, or may be integrally formed therewith. The central tube 340 may include at least two portions, a first portion 360 defining the cavity 344, and a second portion 364 below the first portion 360. The second portion 364 may be solid or hollow and the heights of the first portion 360 and the second portion 364 may be adjusted based on desired flow characteristics of the tank assembly 310.

The flow modifier 342 may extend along a length of the tank 312, from a position below the outlet openings 350 to receive fluid from the inlet to a position above the second tube 328 to deliver fluid to the outlet allowing for the controlled flow of fluid along the length of the tank 312. The flow modifier 342 may be formed by a plurality of plates 382a-182e spaced from one another along a length of the tank 312 and one or more dividers 384, and as shown a divider 384 between each pair of adjacent plates 382 to direct flow around the plates 382 to increase the flow path of the fluid. The dividers 384 may be coupled to the plates 382 in a suitable manner, such as welding, or may be integrally formed therewith. It will also be appreciated that the divider may be formed in one or more pieces that extend along the length of the tank 312 such that ends of the plates 382 are coupled to sides of the dividers 384.

Each plate 382 extends to the inner surface of the tank 312 and is coupled to the inner surface to prevent flow between the tank 312 and the plates 382. The topmost plate 382a defines with the dome 314 an inlet chamber 386, the bottommost plate 382e defines with the dome 316 an outlet chamber 388, and each pair of adjacent plates 382b-382e define therebetween a chamber 390a-390dfor receiving fluid. As shown, the plates 382 are substantially parallel to one another and perpendicular to the central tube 340, although it will be appreciated that the plates could be configured with curves surfaces having variable pitch. It will also be appreciated that any suitable numbers of plates 382 may be utilized.

Each plate 382 includes an opening 392 allowing fluid to flow through the plate 382 to the chamber 390 or 388 below it. As shown, the openings 392 are staggered on opposite sides of the dividers 384 from adjacent plates 382 to increase a travel distance of the fluid flowing through the tank 312. For example, fluid enters the tank 312 via the first tube 326 and is directed through the cavity 344 to exit the outlet opening 340 into the inlet chamber 386 where the fluid flows through the opening 392 in the topmost plate 382a to the chamber 390a between the plates 382a and 382b. The opening 392 in the plate 382b is positioned on an opposite side of the plate 384 from where the fluid enters the chamber 390a, and thus the fluid flows around the plate 382b to exit the opening 392 to the chamber 390b between the plates 382b and 382c. Similarly, the opening 392 in the plate 382c is positioned on an opposite side of the plate 384 from where the fluid enters the chamber 390b, and thus the fluid flows around the plate 382c to exit the opening 392 to the chamber 390c. As shown, the openings 392 in plates 382a, 382c, and 382e are vertically aligned, and the openings 392 in plates 382b and 382d are slightly offset from one another due to the position of the inlet tube 326.

During operation, fluid enters the tank assembly 312 via the first tube 326. The fluid flow through the first tube 326 to the cavity 344 and then exits the cavity 344 via outlet opening 350 into the inlet chamber 3186, where the fluid exits the inlet chamber 386 via the opening 392 in the plate 382a. The fluid flows along the flow modifier 342 through successive chamber 390a-d and corresponding openings 392 to the outlet chamber 388. The fluid then flows from the outlet chamber 388 to the second tube 328 where the fluid exits the tank assembly 310.

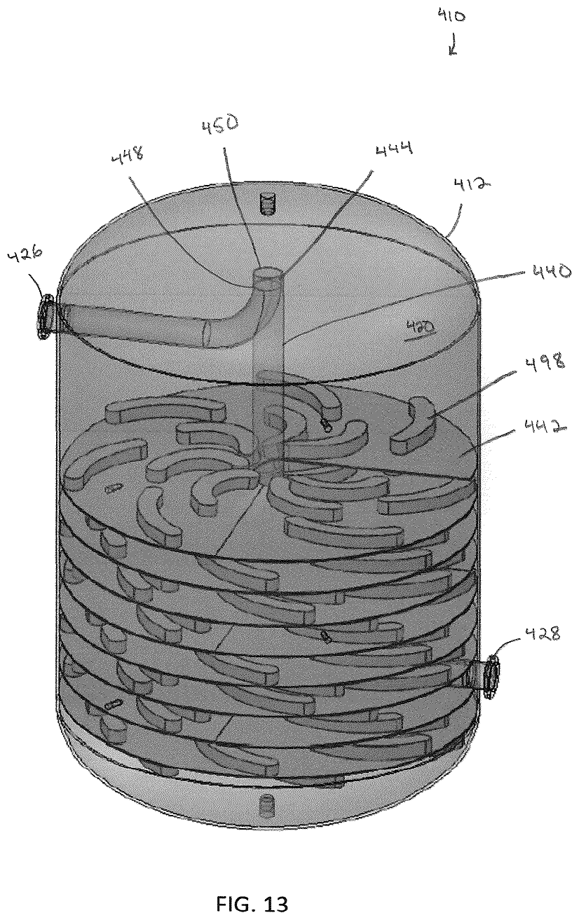

Turning now to FIG. 13, an exemplary embodiment of the tank assembly is shown at 410. The tank assembly 410 is substantially the same as the above-referenced tank assembly 10, and consequently the same reference numerals but indexed by 400 are used to denote structures corresponding to similar structures in the tank assemblies. In addition, the foregoing description of the tank assembly 10 is equally applicable to the tank assembly 410 except as noted below.

The tank assembly 410 includes a tank 412, first and second tubes 426 and 428 extending from the tank, and a flow assembly disposed in a cavity 420 of the tank 412. The flow assembly includes a central tube 440 coupled to the first and second tubes 426 and 428 and a flow modifier 442 coupled to the central tube 440 and/or an inner surface of the tank 412. The central tube 440 extends along a length of the tank 412 and includes a first cavity 444, a second cavity, a first inlet opening 448 through which the first tube 426 extends into the first cavity 444, a first outlet opening 450 through which fluid exits the first cavity 444 of the central tube 440, one or more second inlet openings through which fluid enters the second cavity of the central tube 440, and a second outlet opening through which the second tube 428 extends into the second cavity.

Turning now to the flow modifier 442, the flow modifier 442 is provided in the cavity 420 of the tank 412 to slow down fluid flow, optimize heat transfer, minimize mixing of thermal layers, and mitigate effects of non-isothermal flow. The flow modifier 442 may extend along a length of the tank 412 to deliver fluid to the outlet allowing for the controlled flow of fluid along the length of the tank 412. The flow modifier 442 may be formed by a plurality of curved surfaces with variable pitch along the length of the flow modifier 442 defining a curved path to induce stratification of fluid to maintain temperature gradients. For example, the flow modifier 442 may have a helical pattern designed to direct flow from the top of the tank 412 to the bottom of the tank 412.

The flow modifier 442 may include one or more surface modifiers 498, and as shown, a plurality of surface modifiers 498, such as curved surface modifiers 498 spaced from one another on the upper surface of the flow modifier 442 along the length of the tank 412. The surface modifiers 498 may be provided to further slow the flow of fluid through the tank 412. The surface modifiers 498 may be coupled to the flow modifier 442 or integrally formed therewith, and may be made of a suitable material, such as metal, composite material, etc.

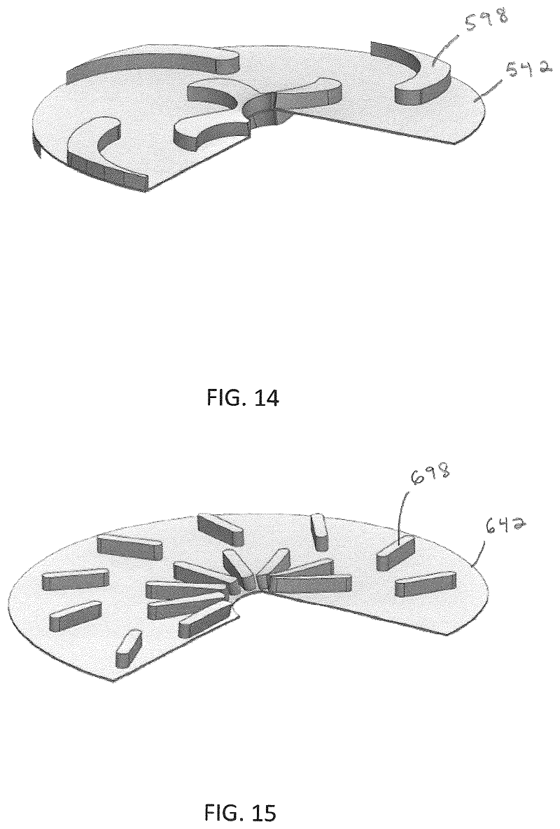

FIGS. 14 and 15 show a portion of alternate flow modifiers 542 and 642 having alternate surface modifiers 598 and 698, respectively. It will be appreciated that the surface modifiers may be combined or configured in a suitable manner. It will also be appreciated that the surface modifiers 498, 598, and/or 698 on the flow modifiers 442, 542, and 642 may be provided with any of the above flow modifiers 42, 142, 242, or 342.

The aforementioned systems, components, (e.g., tanks, flow modifiers, among others), and the like have been described with respect to interaction between several components and/or elements. It should be appreciated that such devices and elements can include those elements or sub-elements specified therein, some of the specified elements or sub-elements, and/or additional elements. Further yet, one or more elements and/or sub-elements may be combined into a single component to provide aggregate functionality. The elements may also interact with one or more other elements not specifically described herein.

While the embodiments discussed herein have been related to the apparatus, systems and methods discussed above, these embodiments are intended to be exemplary and are not intended to limit the applicability of these embodiments to only those discussions set forth herein.

The above examples are merely illustrative of several possible embodiments of various aspects of the present invention, wherein equivalent alterations and/or modifications will occur to others skilled in the art upon reading and understanding this specification and the annexed drawings. In particular regard to the various functions performed by the above described components (assemblies, devices, systems, circuits, and the like), the terms (including a reference to a “means”) used to describe such components are intended to correspond, unless otherwise indicated, to any component, such as hardware, software, or combinations thereof, which performs the specified function of the described component (e.g., that is functionally equivalent), even though not structurally equivalent to the disclosed structure which performs the function in the illustrated implementations of the invention. In addition although a particular feature of the invention may have been disclosed with respect to only one of several implementations, such feature may be combined with one or more other features of the other implementations as may be desired and advantageous for any given or particular application. Also, to the extent that the terms “including”, “includes”, “having”, “has”, “with”, or variants thereof are used in the detailed description and/or in the claims, such terms are intended to be inclusive in a manner similar to the term “comprising.” This written description uses examples to disclose the invention, including the best mode, and also to enable one of ordinary skill in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that are not different from the literal language of the claims, or if they include equivalent structural elements with insubstantial differences from the literal language of the claims.

In the specification and claims, reference will be made to a number of terms that have the following meanings. The singular forms “a”, “an” and “the” include plural referents unless the context clearly dictates otherwise. Approximating language, as used herein throughout the specification and claims, may be applied to modify a quantitative representation that could permissibly vary without resulting in a change in the basic function to which it is related. Accordingly, a value modified by a term such as “about” is not to be limited to the precise value specified. In some instances, the approximating language may correspond to the precision of an instrument for measuring the value. Moreover, unless specifically stated otherwise, a use of the terms “first,” “second,” etc., do not denote an order or importance, but rather the terms “first,” “second,” etc., are used to distinguish one element from another.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable, or suitable. For example, in some circumstances an event or capacity can be expected, while in other circumstances the event or capacity cannot occur-this distinction is captured by the terms “may” and “may be.”

The best mode for carrying out the invention has been described for purposes of illustrating the best mode known to the applicant at the time and enable one of ordinary skill in the art to practice the invention, including making and using devices or systems and performing incorporated methods. The examples are illustrative only and not meant to limit the invention, as measured by the scope and merit of the claims. The invention has been described with reference to preferred and alternate embodiments. Obviously, modifications and alterations will occur to others upon the reading and understanding of the specification. It is intended to include all such modifications and alterations insofar as they come within the scope of the appended claims or the equivalents thereof. The patentable scope of the invention is defined by the claims, and may include other examples that occur to one of ordinary skill in the art. Such other examples are intended to be within the scope of the claims if they have structural elements that do not differentiate from the literal language of the claims, or if they include equivalent structural elements with insubstantial differences from the literal language of the claims.

1. A tank assembly comprising:
a tank having an inlet for receiving fluid and an outlet for delivering fluid, the tank assembly defining a cavity for storing fluid; and
a flow assembly disposed in the cavity, the flow assembly including a flow modifier for directing fluid from the inlet to the outlet while slowing a flow rate of the fluid.

2. The tank assembly according to claim 1, wherein the flow modifier has a helical pattern for directing flow from a top of the tank to a bottom of the tank.

3. The tank assembly according to claim 2, wherein the inlet and outlet are provided on opposite side of the tank and extend in opposite directions from one another perpendicular to a central axis of the tank, and wherein the outlet is below the inlet.

4. The tank assembly according to claim 1, wherein the flow assembly additionally includes a central tube disposed in the cavity and coupled to the flow modifier.

5. The tank assembly according to claim 4, further including an inlet tube extending through the inlet of the tank and being coupled to the central tube, and an outlet tube extending through the outlet of the tank and being coupled to the central tube.

6. The tank assembly according to claim 5, wherein the central tube includes a first cavity, a second cavity, a first inlet opening through which the first tube extends into the first cavity, one or more first outlet openings through which fluid exits the first cavity, one or more second inlet openings through which fluid enters the second cavity, and a second outlet opening through which the second tube extends into the second cavity.

7. The tank assembly according to claim 6, wherein the flow modifier extends along a length of the tank from a position below the first outlet opening to receive fluid from the inlet to a position above the second inlet opening to deliver fluid to the outlet.

8. The tank assembly according to claim 4, wherein the flow modifier extends along a length of the tank from a position below the inlet to a position above the outlet.

9. The tank assembly according to claim 8, wherein the flow modifier includes a plurality of plates spaced from one another along a length of the tank, and one or more dividers between each pair of adjacent plates.

10. The tank assembly according to claim 9, wherein the plurality of plates are substantially parallel to one another and perpendicular to the central tube.

11. The tank assembly according to claim wherein each plate includes a plate opening for fluid to flow downward through the tank.

12. The tank assembly according to claim 11, wherein the plate openings are staggered on opposite sides of the one or more dividers from plate openings in adjacent plates.

13. The tank assembly according to claim 1, wherein the tank is formed by an upper dome, a lower dome, and a shell having a first end connected to the upper dome and a second end connected to the lower dome.

14. A tank assembly comprising:
a tank having an inlet for receiving fluid and an outlet for delivering fluid, the tank assembly defining a cavity for storing fluid;
an inlet tube coupled to the tank at the inlet;
an outlet tube coupled to the tank at the outlet below the inlet; and
a flow assembly disposed in the cavity, the flow assembly including a flow modifier for directing fluid from the inlet to the outlet while slowing a flow rate of the fluid and a central tube coupled to the flow modifier.

15. The tank assembly according to claim 14, wherein the inlet tube extends through the inlet of the tank and is coupled to the central tube and the outlet tube extends through the outlet of the tank and is coupled to the central tube, and wherein the central tube includes a first cavity, a second cavity, a first inlet opening through which the first tube extends into the first cavity, one or more first outlet openings through which fluid exits the first cavity, one or more second inlet openings through which fluid enters the second cavity, and a second outlet opening through which the second tube extends into the second cavity.

16. The tank assembly according to claim 14, wherein the flow modifier has a helical pattern for directing flow from a top of the tank to a bottom of the tank.

17. The tank assembly according to claim 15, wherein the flow modifier extends along a length of the tank from a position below the first outlet opening to receive fluid from the inlet to a position above the second inlet opening to deliver fluid to the outlet.

18. The tank assembly according to claim 14, wherein the flow modifier includes a plurality of plates substantially parallel to one another along a length of the tank and perpendicular to the central tube, and one or more dividers between each pair of adjacent plates.

19. The tank assembly according to claim 18, wherein each plate includes a plate opening for fluid to flow downward through the tank, and wherein the plate openings are staggered on opposite sides of the one or more dividers from plate openings in adjacent plates.

20. A tank assembly comprising:
a tank having an inlet for receiving fluid and an outlet for delivering fluid, the tank assembly defining a cavity for storing fluid;
an inlet tube coupled to the tank at the inlet;
an outlet tube coupled to the tank at the outlet below the inlet, the inlet tube and outlet tube being on opposite sides of the tank and extending in opposite directions from one another perpendicular to a central axis of the tank; and
a flow assembly disposed in the cavity, the flow assembly including a flow modifier for directing fluid from the inlet to the outlet while slowing a flow rate of the fluid and a central tube coupled to the flow modifier,
wherein the flow modifier has a helical pattern for directing flow from a top of the tank to a bottom of the tank, or
wherein the flow modifier includes a plurality of plates spaced from one another along a length of the tank and one or more dividers between each pair of adjacent plates, and wherein each plate includes a plate opening for fluid to flow downward through the tank.
